(19) United States
(12) Patent Application Publication
(10) Pub. No.: US 2021/0057348 A1
(43) Pub. Date: Feb. 25, 2021

(54) BARRIER MATERIALS BETWEEN BUMPS AND PADS

(71) Applicant: Intel Corporation, Santa Clara, CA (US)

(72) Inventors: Ehren HWANG, Portland, OR (US); Christopher M. PELTO, OR (US); Seshu V. SATTIRAJU, Portland, OR (US); Shravan GOWRISHANKAR, Beaverton, OR (US); Zachary A. ZELL, Portland, OR (US); Digvijay A. RAORANE, Chandler, AZ (US)

(21) Appl. No.: 16/650,292

(22) PCT Filed: Dec. 19, 2017
(86) PCT No.: PCT/US2017/067227

§ 371 Date: Mar. 24, 2020

(51) Int. Cl. H01L 23/532; H01L 21/768; H01L 23/498; H01L 23/522; H01L 23/528

(52) U.S. Cl. CPC H01L 23/53238; H01L 21/76843; H01L 23/5283; H01L 23/49811; H01L 23/5226; H01L 21/76871

(57) ABSTRACT

Disclosed are barrier materials between bumps and pads, and related devices and methods. A semiconductor device includes an interconnect, a top material, a pad on the interconnect and at least a portion of the top material, a bump on the pad, and a barrier material between the pad and the bump. The top material defines a via therethrough to the interconnect. The pad includes electrically conductive material. The bump includes electrically conductive material. The bump is configured to electrically connect the interconnect to another device. The barrier material is between the pad and the bump. The barrier material includes a conductive material that is resistant to electromigration, intermetallic compound reaction, or both electromigration and intermetallic compound reaction.

### BACKGROUND

Controlled collapse chip connection (C4) enables connection (e.g., electrical and mechanical) of semiconductor devices (e.g., integrated circuits) to other devices (e.g., printed circuit boards (PCBs), other semiconductor devices, etc.).

### BRIEF DESCRIPTION OF THE DRAWINGS

FIG. 1 is a simplified cross-sectional view of a semiconductor device, according to some embodiments.

FIG. 2 is a simplified flowchart illustrating a method of manufacturing a semiconductor device, according to some embodiments.

FIGS. 3A-3F are simplified cross-sectional views illustrating acts of the method of FIG. 2.

FIG. 4 is a simplified plot comparing time to fail (TTF) distributions for joints that include barrier materials to TTF distributions for joints that do not include barrier materials.

FIG. 5 is a simplified plot comparing cumulative probability against TTF for joints including barrier materials and joints not including barrier materials.

FIG. 6 illustrates an interposer that includes one or more embodiments of the disclosure.

FIG. 7 illustrates a computing device in accordance with one embodiment of the disclosure.

### DETAILED DESCRIPTION

Described herein are barrier materials between bumps and pads of semiconductor devices, and related devices and methods. In the following description, various aspects of the illustrative implementations will be described using terms commonly employed by those skilled in the art to convey the substance of their work to others skilled in the art. However, it will be apparent to those skilled in the art that the disclosure may be practiced with only some of the described aspects. For purposes of explanation, specific numbers, materials and configurations are set forth in order to provide a thorough understanding of the illustrative implementations. However, it will be apparent to one skilled in the art that the disclosure may be practiced without the specific details. In other instances, well-known features are omitted or simplified in order not to obscure the illustrative implementations.

Various operations will be described as multiple discrete operations, in turn, in a manner that is most helpful in understanding the disclosure. The order of the description, however, should not be construed to imply that these operations are necessarily order dependent. In particular, these operations need not be performed in the order of presentation.

The terms “over,” “under,” “between,” and “on,” as used herein, refer to a relative position of one material (e.g., region, structure, layer, etc.) or component with respect to other materials (e.g., regions, structures, layers, etc.) or components. For example, one material disposed over, under, or on another material may be directly in contact with the other material or may have one or more intervening materials. Moreover, one material disposed between two materials may be directly in contact with the two materials or may have one or more intervening materials. Moreover, to the extent that the terms “over,” “under,” and “on” imply a vertical orientation, such orientation is not intended to be limiting herein. Rather, it is noted that a vertically oriented structure or structures may be equivalently implemented horizontally, at some non-vertical and non-horizontal orientation, in an angular orientation, or in various non-linear orientations.

Implementations of the disclosure may be formed or carried out on a substrate, such as a semiconductor substrate. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, indium antimonide, lead telluride, indium arsenide, indium phosphide, gallium arsenide, indium gallium arsenide, gallium antimonide, or other combinations of group III-V, group II-VI, or group IV materials. Although a few examples of materials from which the substrate may be formed are described here, any material that may serve as a foundation upon which a semiconductor device may be built falls within the spirit and scope of the disclosure.

Electromigration and intermetallic composite formation have increasingly become issues with the scaling of semiconductor devices, and with high-current drive electronics. When not addressed, these issues can lead to material loss and subsequent failure of joints between conductive structures, and ultimately product failure. These issues are particularly prevalent where a device operates near its maximum current (I_{MAX}).

Disclosed herein are barrier materials between bumps and pads. These barrier materials are resistant to electromigration, intermetallic composite formation, or combinations thereof. These barrier materials enable improved I_{MAX} reliability performance while maintaining the standard wafer (e.g., silicon (Si)) side bump (e.g., a planar or non-planar bump or interconnect), and allowing the same or similar attach process to be used downstream. Techniques that are currently in use in industry place a barrier layer near the top of the standard joint between the die side pad and the solder material. These solutions are unlike the disclosure, where the material is submerged (e.g., completely submerged) underneath the existing metallization and does not come into contact with solder or other downstream material sets.

A barrier material that is resistant to electromigration, intermetallic composite formation, or both is embedded at the base of a die size bump. The introduction of this barrier material enhances I_{MAX} performance by slowing down intermetallic formation and leeching of the bump metallization, which may prevent material loss and subsequent failure of the joint and, eventually, failure of the product. The barrier material may slow intermetallic composite growth between the bump metallization and solder, which may reduce the formation of Kirkendall voids that can eventually coalesce into catastrophic joint separation and electrical failure.

Embodiments disclosed herein may provide significant improvement in I_{MAX} performance as compared to devices that do not include barrier materials between bumps and pads, particularly in cases where the existing metallization is too thin to survive reliably without the barrier materials. By placing the barrier material at the bottom of a stack, the outer interfaces are kept standard, and this process is thus transparent to downstream processing that interacts with the joint surface.

A barrier material and a pad may together form a binary stack within a joint. The barrier material thickness may be scaled by volumetric substitution of the materials of the binary stack. Also, the upper metallization (e.g., the bump) may function as a buffer against barrier layer material reaction by protecting the barrier material from direct exposure to solder or other reactive materials.

According to embodiments disclosed herein, standard bump metallurgy may be maintained without increasing the bump height or volume to provide a sacrificial barrier. For example, copper (Cu) bumps may be useful in devices having tight pitch bump design rules (e.g., in advanced flip chip packaging) due to fine patterning control and robust sort probing. Increasing the bump height would challenge the lithography process and bring thermomechanical risk by increasing the amount of stiff metal in the joint. Embodiments disclosed herein may be implemented without increasing the height or volume of the bump, as compared to prior known devices.

As used herein, the term “barrier material” refers to materials that are resistant to electromigration, intermetallic compound reaction, or both. Examples of these materials include metals (e.g., tantalum (Ta), tungsten (W), platinum (Pt), nickel (Ni), cobalt (Co), or silver (Ag)), composites (e.g., conductive ceramics, conductive polymers such as carbon nanotubes, etc.), or combinations thereof. These materials exhibit relatively low solder reaction rates, relatively high electromigration resistance, or combinations thereof. As a result, these materials, when used as disclosed herein, may slow the failure rate of conductive joints due to I_{MAX} stress-related wear-out failure.

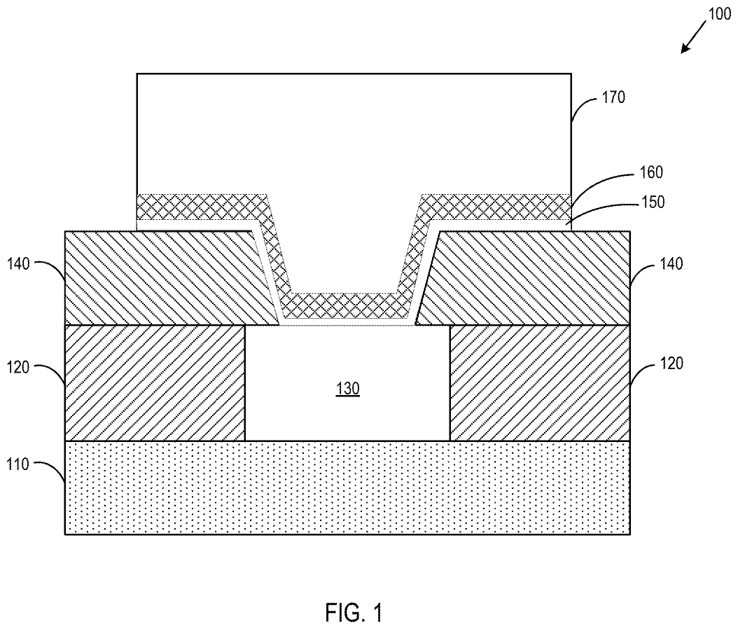

FIG. 1 is a simplified cross-sectional view of a semiconductor device 100, according to some embodiments. The semiconductor device 100 includes a semiconductor wafer 110 (sometimes referred to herein simply as “wafer” 110), at least one interlayer dielectric (ILD) 120 on the wafer 110, an interconnect 130 formed through the ILD 120, and a top material 140 (e.g., an electrically insulating material such as a dielectric). The top material 140 defines a passage (e.g., a via) therethrough to the interconnect 130. The semiconductor device 100 also includes a pad 150 on the interconnect 130 and at least a portion of the top material 140, and a bump 170 on the pad 150. The pad 150 and the bump 170 include electrically conductive material (e.g., the same material, different materials). The semiconductor device 100 further includes a barrier material 160 between the pad 150 and the bump 170. The barrier material 160 includes a conductive material that is resistant to electromigration, intermetallic compound reaction, or both electromigration and intermetallic compound reaction.

In some embodiments, the barrier material 160 includes a metal. By way of non-limiting example, the barrier material 160 may include tantalum (Ta), tungsten (W), platinum (Pt), nickel (Ni), cobalt (Co), silver (Ag), or combinations thereof. In some embodiments, the barrier material 160 includes a conductive ceramic material. In some embodiments, the barrier material 160 includes a conductive polymer material (e.g., one or more carbon nanotubes).

In some embodiments, the barrier material 160 completely separates the bump 170 from the pad 150. In some embodiments, however, the barrier material 160 may only partially separate the bump 170 from the pad 150.

In some embodiments, the barrier material 160 is conformal to the top material 140 and the interconnect 130 in the shape of the via. In some embodiments, the barrier material 160 is of a relatively uniform thickness, as shown in FIG. 1. In some embodiments, a thickness profile of the barrier material 160 may depend on how much of the barrier material is used to enable a particular application.

The bump 170 may include a planar bump or a non-planar bump. In some embodiments, the bump 170 includes copper. In some embodiments, the bump 170 and the pad 150 include the same electrically conductive material. In some embodiments, the bump 170 and the pad 150 may include different materials. By way of non-limiting example, the bump 170 may include copper (Cu) and the pad 150 may include titanium (Ti) (e.g., elemental titanium (Ti), titanium nitride (TiN), di-titanium nitride (Ti₂N), etc.). In some embodiments, a seed material used to form the barrier material 160 may be located between the pad 150 and the barrier material 160.

The at least one ILD 120 is deposited over the wafer 110. The wafer 110 may include one or more electronic devices formed therein or thereon (e.g., MOS transistors, etc.). The ILD 120 may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD 120 may include pores or air gaps to further reduce its dielectric constant.

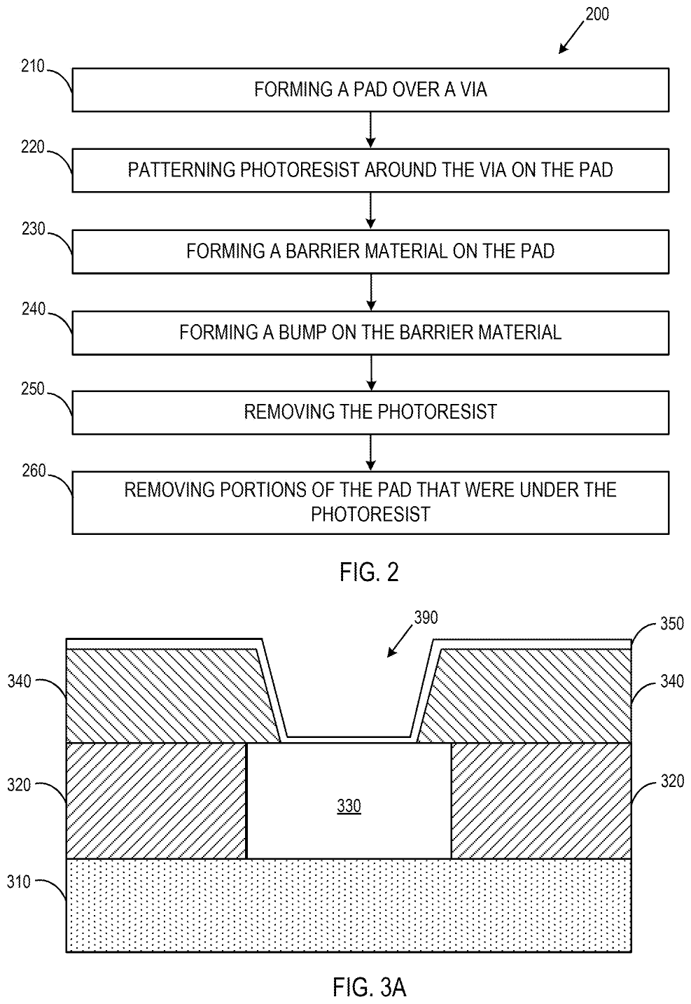

FIG. 2 is a simplified flowchart illustrating a method 200 of manufacturing a semiconductor device (e.g., the semiconductor device 100 of FIG. 1), according to some embodiments.

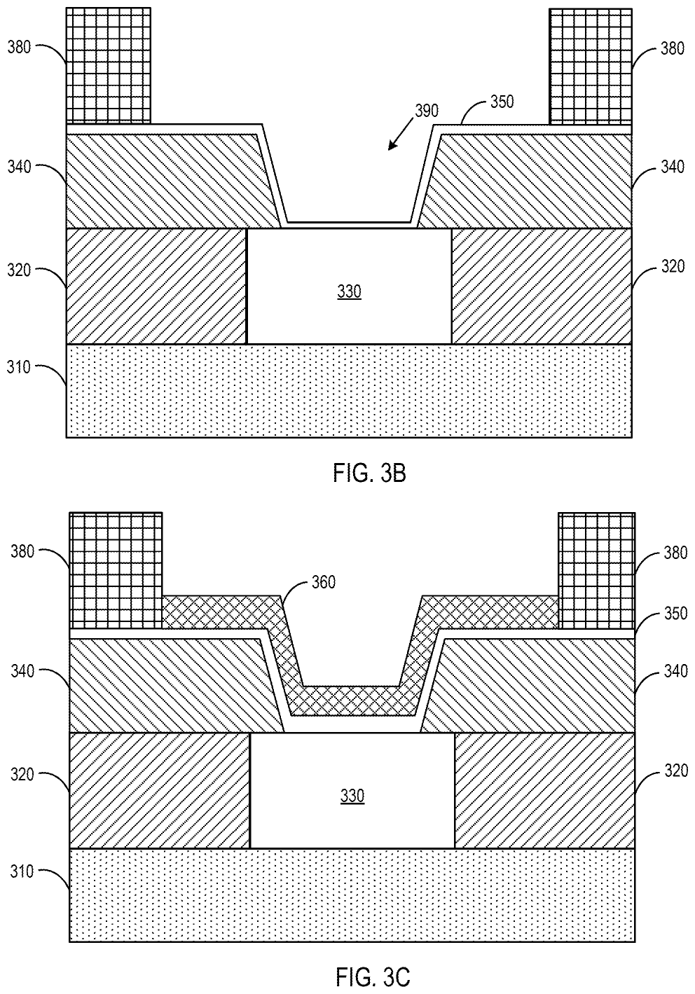

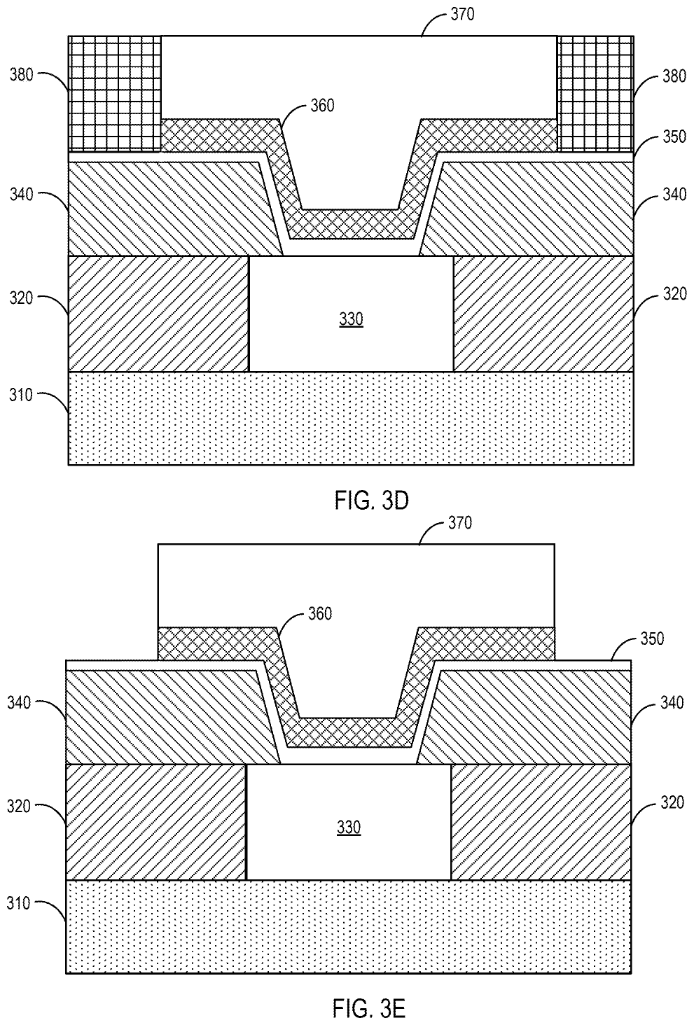

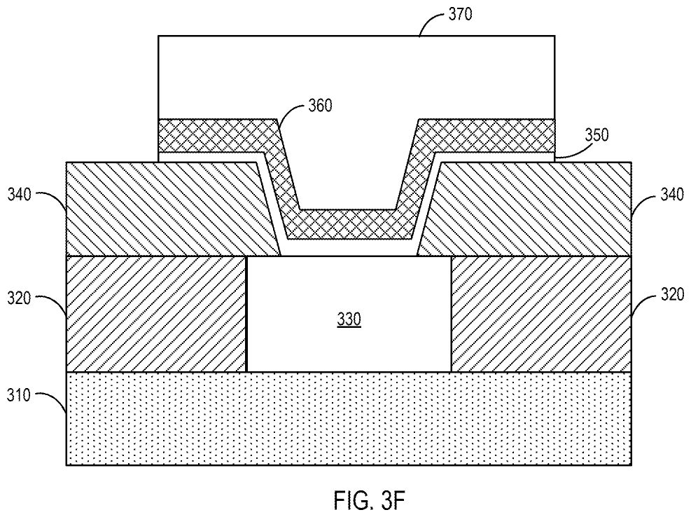

FIGS. 3A-3F are simplified cross-sectional views illustrating acts of the method 200 of FIG. 2.

Referring to FIGS. 2 and 3A-3F together, the method 200 includes forming 210 a pad 350 including an electrically conductive material over a via 390. FIG. 3A illustrates the pad 350 on the via 390. As also illustrated in FIG. 3A, the via 390 may be formed through a top material 340 (e.g., an electrically insulating material such as a dielectric) to an interconnect 330 traversing an ILD 320 on a wafer 310. The pad 350, the top material 340, the interconnect 330, the ILD 320, and the wafer 310 may be similar to the pad 150, the top material 140, the interconnect 130, the ILD 120, and the wafer 110 discussed above with reference to FIG. 1. The method 200 also includes patterning 220 photoresist 380 around the via 390 on the pad 350. FIG. 3B illustrates the photoresist 380 around the via 390.

The method 200 further includes forming 230 a barrier material 360 on the pad 350. FIG. 3C illustrates the barrier material 360 on the pad 350. The barrier material 360 includes electrically conductive material selected to resist electromigration, intermetallic compound reaction, or both electromigration and intermetallic compound reaction. The barrier material 360 may be similar to the barrier material 160 discussed above with reference to FIG. 1. In some embodiments, forming 230 a barrier material 360 on the pad 350 includes forming a seed material on the pad 350 and forming the barrier material 360 using the seed material. In some embodiments, forming 230 a barrier material 360 on the pad 350 includes depositing the barrier material 360 on the pad 350 using chemical vapor deposition (CVD). In some embodiments, forming 230 a barrier material 360 on the pad 350 includes depositing the barrier material 360 on the pad 350 using physical vapor deposition (PVD). In some embodiments, forming 230 a barrier material 360 on the pad 350 includes sputtering the barrier material 360 onto the pad 350.

The method 200 also includes forming 240 a bump 370 including electrically conductive material on the barrier material 360. FIG. 3D illustrates the bump 370 on the barrier material 360. The method 200 further includes removing 250 the photoresist 380. FIG. 3E illustrates the device with the photoresist 380 removed therefrom. The method 200 also includes removing 260 portions of the pad 350 that were under the photoresist 380. FIG. 3F illustrates the device with the portions of the pad 350 removed therefrom. In some embodiments, removing 260 portions of the pad 350 includes etching away the portions of the pad 350.

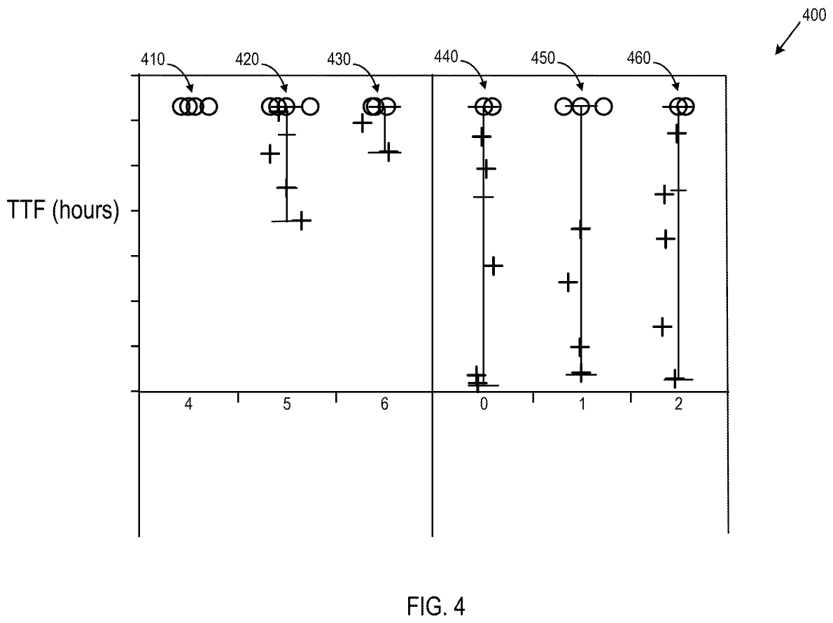

FIG. 4 is a simplified plot 400 comparing time to fail (TTF) distributions 410, 420, 430 for joints that include barrier materials (e.g., the barrier materials 160, 360) to TTF distributions 440, 450, 460 for joints that do not include barrier materials. In the plot 400 of FIG. 4 the vertical axis illustrates time to fail (TTF), and the horizontal axis illustrates number of runs (e.g., number of runs of operating the joints at maximum current (I_{MAX})). Failures are illustrated using “+” and non-failures are illustrated using “−.”

As illustrated by the plot 400, the joints that include barrier materials were capable of a greater number of runs for a longer period of time without failures than were the joints that did not include the barrier materials. This illustrates the improved I_{MAX} performance of the joints with the barrier materials as compared to the joints without the barrier materials.

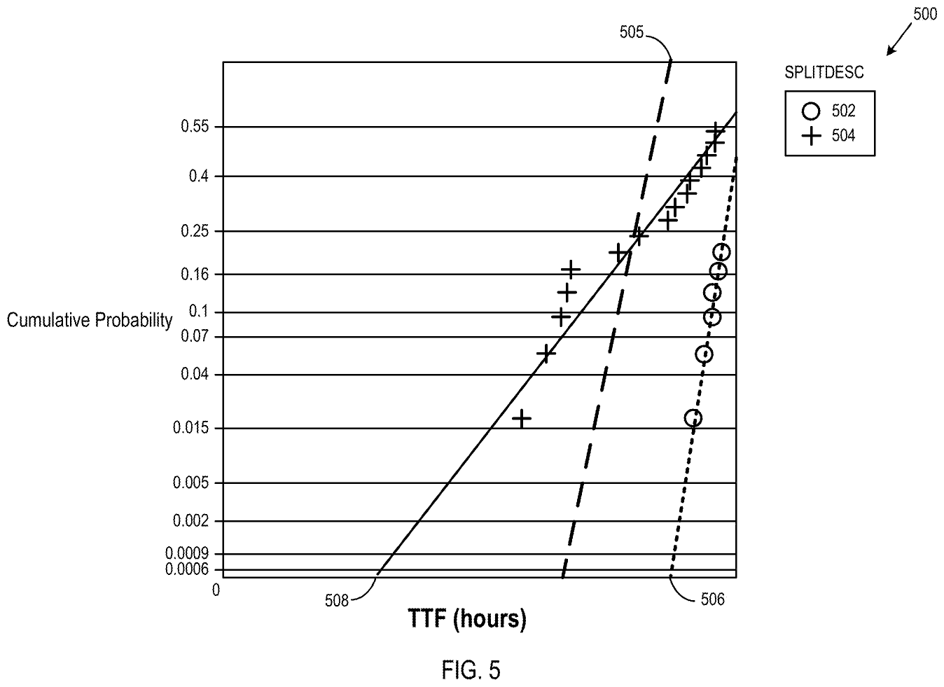

FIG. 5 is a simplified plot 500 comparing cumulative probability against TTF for joints including barrier materials (data points shown as “o,” which corresponds to reference numeral 502) and joints not including barrier materials (data points shown as “+,” which corresponds to reference numeral 504). Linear regressions 506, 508 of the data points 502, 504 are also illustrated. As can be seen by inspecting the plot 500, experimental validation demonstrates significant reliability performance gains in I_{MAX} stress for joints including barrier materials, as discussed herein. When viewed as a lifetime distribution, the joints including the barrier materials significantly improve both the failure time and the intrinsic characteristics of the overall failure distribution (e.g., more vertical linear regression 506 than linear regression 508, and linear regression 506 located further to the right of reference line 505 than linear regression 508). Also, the difference in slope between the linear regressions 506, 508 indicates a change in the kinetics of the failure mechanism responsive to the barrier materials, resulting in a global improvement in capability.

Although the barrier materials 160, 360 discussed herein are discussed primarily in the context of C4 applications, the disclosure is not so limited. For example, the barrier materials 160, 360 may be used in soldering applications (e.g., tin copper (SnCu), tin-silver-copper 105 (SAC105), tin-silver-copper 305 (SAC305), or tin silver (SnAg) solders), in first level interconnect (FLI) connection applications (e.g., flip chip, bond on trace, wafer level packaging, etc.), in substrate and/or package applications (polymer, ceramic, chip-scale package (CSP)), in architecture applications (high-speed interconnects such as embedded multi-die interconnect bridge (EMIB), three-dimensional chip stacking, monolithic devices), in connection to board applications (e.g., land grid array (LGA), ball grid array (BGA)), and in applications involving attachment of a die to a substrate using anisotropically conductive adhesive (ACA) flip chip without solder.

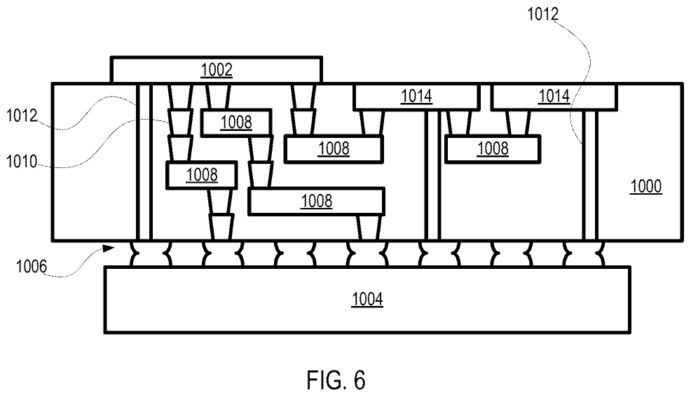

FIG. 6 illustrates an interposer 1000 that includes one or more embodiments of the disclosure. The interposer 1000 is an intervening substrate used to bridge a first substrate 1002 to a second substrate 1004. The first substrate 1002 may be, for instance, an integrated circuit die (e.g., the semiconductor device 100 of FIG. 1). The second substrate 1004 may be, for instance, a memory module, a computer motherboard, or another integrated circuit die (e.g., the semiconductor device 100 of FIG. 1). Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer 1000 may be formed of alternate rigid or flexible materials that may include the same materials described above for use in a semiconductor substrate, such as silicon, germanium, and other group III-V and group IV materials.

The interposer may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000.

In accordance with embodiments of the disclosure, apparatuses or processes disclosed herein may be used in the fabrication of interposer 1000.

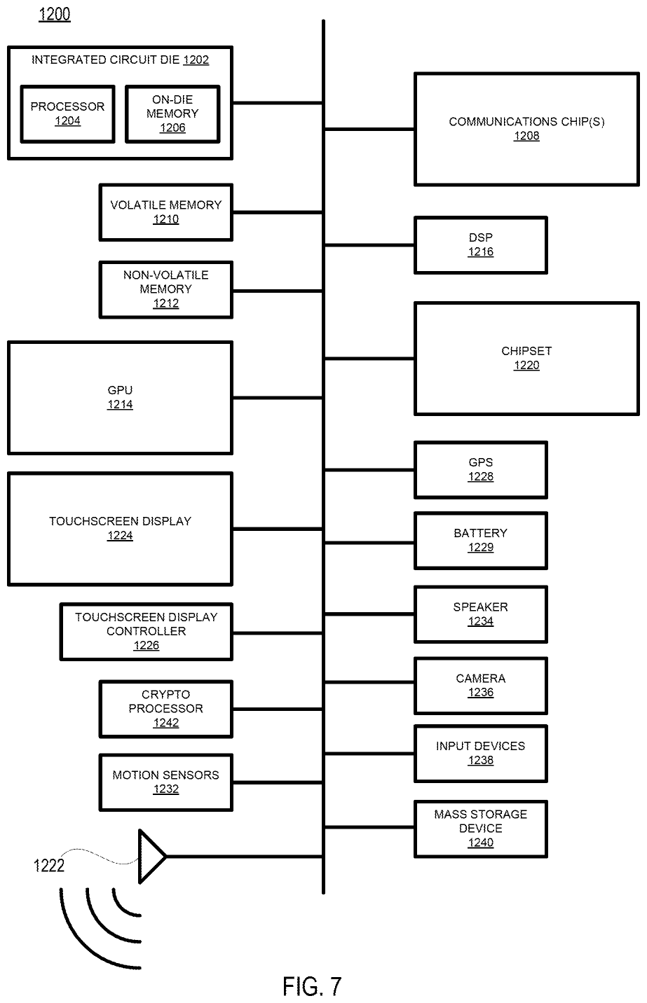

FIG. 7 illustrates a computing device 1200 in accordance with one embodiment of the disclosure. The computing device 1200 may include a number of components. In one embodiment, these components are attached to one or more motherboards (e.g., using bumps connected to wafers via barrier materials, as discussed above). In an alternate embodiment, some or all of these components are fabricated onto a single system-on-a-chip (SoC) die, such as an SoC used for mobile devices. The components in the computing device 1200 include, but are not limited to, an integrated circuit die 1202 and at least one communications chip 1208 (also referred to herein as “communications logic unit” 1208). In some implementations the communications chip 1208 is fabricated within the integrated circuit die 1202 while in other implementations the communications logic unit 1208 is fabricated in a separate integrated circuit chip that may be bonded to a substrate or motherboard that is shared with or electronically coupled to the integrated circuit die 1202. The integrated circuit die 1202 may include a processor 1204 (e.g., a CPU) as well as on-die memory 1206, often used as cache memory, which can be provided by technologies such as embedded DRAM (eDRAM), SRAM, or spin-transfer torque memory (STT-M RAM).

Computing device 1200 may include other components that may or may not be physically and electrically coupled to the motherboard (e.g., using bumps connected to wafers via barrier materials, as discussed above) or fabricated within an SoC die. These other components include, but are not limited to, volatile memory 1210 (e.g., DRAM), non-volatile memory 1212 (e.g., ROM or flash memory), a graphics processing unit (GPU) 1214, a digital signal processor (DSP) 1216, a crypto processor 1242 (e.g., a specialized processor that executes cryptographic algorithms within hardware), a chipset 1220, at least one antenna 1222 (in some implementations two or more antenna may be used), a display or a touchscreen display 1224, a touchscreen display controller 1226, a battery 1229 or other power source (not shown), a power amplifier (not shown), a voltage regulator (not shown), a global positioning system (GPS) device 1228, a compass (not shown), one or more motion sensors 1232 (e.g., a motion coprocessor such as an accelerometer, a gyroscope, a compass, etc.), a microphone (not shown), a speaker 1234, a camera 1236, user input devices 1238 (such as a keyboard, mouse, stylus, and touchpad), and a mass storage device 1240 (such as hard disk drive, compact disk (CD), digital versatile disk (DVD), and so forth). The computing device 1200 may incorporate further transmission, telecommunication, or radio functionality not already described herein. In some implementations, the computing device 1200 includes a radio that is used to communicate over a distance by modulating and radiating electromagnetic waves in air or space. In further implementations, the computing device 1200 includes a transmitter and a receiver (or a transceiver) that is used to communicate over a distance by modulating and radiating electromagnetic waves in air or space.

The communications chip 1208 may include a communications logic unit configured to transfer data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 1208 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 1200 may include a plurality of communications chips 1208. For instance, a first communications chip 1208 may be dedicated to shorter range wireless communications such as Wi-Fi, NFC, and Bluetooth and a second communications chip 1208 may be dedicated to longer range wireless communications such as GPS, EDGE, GPRS, CDMA, WiMAX, LTE, Ev-DO, and others.

The processor 1204 of the computing device 1200 includes one or more devices, such as the semiconductor device 100 of FIG. 1. The term “processor” may refer to any device or portion of a device that processes electronic data from registers and/or memory to transform that electronic data into other electronic data that may be stored in registers and/or memory.

The communications logic unit 1208 may also include one or more devices, such as the semiconductor device 100 of FIG. 1.

In further embodiments, another component housed within the computing device 1200 may contain one or more devices, such as the semiconductor device 100 of FIG. 1.

In various embodiments, the computing device 1200 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1200 may be any other electronic device that processes data.

In some embodiments, a computing device includes a semiconductor device. The semiconductor device includes a top material defining a via formed therethrough, and a pad including electrically conductive material lining the via, the pad electrically connected to at least one device of the semiconductor device. The semiconductor device also includes a barrier material on the pad, the barrier material comprising electrically conductive material selected to resist electromigration, intermetallic compound reaction, or both electromigration and intermetallic compound reaction. The semiconductor device further includes a bump comprising electrically conductive material on the barrier material. In some embodiments, the computing device includes a printed circuit board (PCB) (e.g., a motherboard). In such embodiments, the semiconductor device may be electrically connected to the PCB through the bump. In some embodiments, the computing device further includes a processor mounted on a substrate, a memory unit capable of storing data, a graphics processing unit, an antenna within the computing device, a display on the computing device, a battery within the computing device, a power amplifier within the processor, and a voltage regulator within the processor. At least one of the processor, the memory unit, the graphics processing unit, the antenna, the display, the battery, the power amplifier, or the voltage regulator includes the semiconductor device.

### EXAMPLES

The following is a non-exhaustive list of example embodiments that fall within the scope of the disclosure. In order to avoid complexity in providing the disclosure, not all of the examples listed below are separately and explicitly disclosed as having been contemplated herein as combinable with all of the others of the examples listed below and other embodiments disclosed hereinabove. Unless one of ordinary skill in the art would understand that these examples listed below, and the above disclosed embodiments, are not combinable, it is contemplated within the scope of the disclosure that such examples and embodiments are combinable.

Example 1: A semiconductor device, comprising: an interconnect; a top material defining a via therethrough to the interconnect; a pad comprising electrically conductive material on the interconnect and at least a portion of the top material; a bump comprising electrically conductive material on the pad, the bump configured to electrically connect the interconnect to another device; and a barrier material between the pad and the bump, the barrier material comprising a conductive material that is resistant to electromigration, intermetallic compound reaction, or both electromigration and intermetallic compound reaction.

Example 2: The semiconductor device of Example 1, wherein the barrier material completely separates the bump from the pad.

Example 3: The semiconductor device according to any one of Examples 1 and 2, wherein the barrier material is conformal to a shape of the via.

Example 4: The semiconductor device according to any one of Examples 1-3, wherein the barrier material comprises a metal.

Example 5: The semiconductor device according to any one of Examples 1-4, wherein the barrier material comprises at least one metal selected from the group consisting of tantalum (Ta), tungsten (W), platinum (Pt), nickel (Ni), cobalt (Co), and silver (Ag).

Example 6: The semiconductor device according to any one of Examples 1-5, wherein the barrier material comprises a ceramic material.

Example 7: The semiconductor device according to any one of Examples 1-6, wherein the barrier material comprises a polymer material.

Example 8: The semiconductor device according to any one of Examples 1-7, wherein the bump comprises a planar bump.

Example 9: The semiconductor device according to any one of Examples 1-8, wherein the pad and the bump comprise the same electrically conductive material.

Example 10: The semiconductor device according to any one of Examples 1-9, wherein the bump comprises copper (Cu).

Example 11: An electronic device, comprising: one or more devices formed on or in a substrate; a structure comprising a conductive material, the structure electrically connected to at least one of the one or more devices; a top material on the structure, the top material defining a passage therethrough to the structure; a pad on the structure, the pad comprising electrically conductive material electrically connected to the at least one of the one or more devices through the structure; a bump to electrically connect the at least one of the one or more devices to a device external to the electrical device, the bump comprising electrically conductive material; and a barrier material between the bump and the pad, the barrier material comprising electrically conductive material configured to resist electromigration, intermetallic compound reaction, or both electromigration and intermetallic compound reaction.

Example 12: The electronic device of Example 11, wherein the structure comprises an interconnect that traverses an interlayer dielectric on the substrate.

Example 13: The electronic device according to any one of Examples 11 and 12, wherein the barrier material comprises at least one of a metal, a conductive ceramic, or a conductive polymer.

Example 14: The electronic device according to any one of Examples 11-13, wherein the barrier material comprises one or more carbon nanotubes.

Example 15: The electronic device according to any one of Examples 11-14, further comprising a seed material between the pad and the barrier material, the seed material comprising a material that was used to form the barrier material.

Example 16: A method of manufacturing a semiconductor device, the method comprising: forming a pad comprising an electrically conductive material over a via; patterning photoresist around the via on the pad; forming a barrier material on the pad, the barrier material comprising electrically conductive material selected to resist electromigration, intermetallic compound reaction, or both electromigration and intermetallic compound reaction; forming a bump comprising electrically conductive material on the barrier material.

Example 17: The method of Example 16, wherein forming a barrier material on the pad comprises forming a seed material on the pad and forming the barrier material using the seed material.

Example 18: The method of Example 16, wherein forming a barrier material on the pad comprises depositing the barrier material on the pad using chemical vapor deposition.

Example 19: The method of Example 16, wherein forming a barrier material on the pad comprises depositing the barrier material on the pad using physical vapor deposition.

Example 20: The method of Example 16, wherein forming a barrier material on the pad comprises sputtering the barrier material onto the pad.

Example 21: A computing device, comprising: a semiconductor device including: a top material defining a via formed therethrough; a pad comprising electrically conductive material lining the via, the pad electrically connected to at least one device of the semiconductor device; a barrier material on the pad, the barrier material comprising electrically conductive material selected to resist electromigration, intermetallic compound reaction, or both electromigration and intermetallic compound reaction; and a bump comprising electrically conductive material on the barrier material.

Example 22: The computing device of Example 21, further comprising a printed circuit board (PCB), wherein the semiconductor device is electrically connected to the PCB through the bump.

Example 23: The computing device according to any one of Examples 21-22, further comprising: a processor mounted on a substrate; a memory unit capable of storing data; a graphics processing unit; an antenna within the computing device; a display on the computing device; a battery within the computing device; a power amplifier within the processor; and a voltage regulator within the processor; wherein at least one of the processor, the memory unit, the graphics processing unit, the antenna, the display, the battery, the power amplifier, or the voltage regulator comprises the semiconductor device.

Example 24: A method of forming a semiconductor device, comprising: forming an interconnect; forming a via to the interconnect through a top material; forming a pad comprising electrically conductive material on the interconnect and at least a portion of the top material; forming a bump comprising electrically conductive material on the pad, the bump configured to electrically connect the interconnect to another device; and forming a barrier material between the pad and the bump, the barrier material comprising a conductive material that is resistant to electromigration, intermetallic compound reaction, or both electromigration and intermetallic compound reaction.

Example 25: The method of Example 24, wherein forming a barrier material comprises completely separating the bump from the pad with the barrier material.

Example 26: The method according to any one of Examples 24 and 25, wherein forming the barrier material comprises forming a conformal barrier material that conforms to a shape of the via.

Example 27: The method according to any one of Examples 24-26, wherein forming the barrier material comprises forming the barrier material with metal.

Example 28: The method according to any one of Examples 24-27, wherein forming the barrier material comprises forming the barrier material with at least one metal selected from the group consisting of tantalum (Ta), tungsten (W), platinum (Pt), nickel (Ni), cobalt (Co), and silver (Ag).

Example 29: The method according to any one of Examples 24-28, wherein forming the barrier material comprises forming the barrier material with a ceramic material.

Example 30: The method according to any one of Examples 24-29, wherein forming the barrier material comprises forming the barrier material with a polymer material.

Example 31: The method according to any one of Examples 24-30, wherein forming a bump comprises forming a planar bump.

Example 32: The method according to any one of Examples 24-31, wherein forming a pad and a bump comprise forming the pad and the bump with the same electrically conductive material.

Example 33: The method according to any one of Examples 24-32, wherein forming a bump comprises forming the bump with copper (Cu).

Example 34: A method of forming an electronic device, the method comprising: forming one or more devices on or in a substrate; forming a structure comprising a conductive material, the structure electrically connected to at least one of the one or more devices; forming a top material on the structure, the top material defining a passage therethrough to the structure; forming a pad on the structure, the pad comprising electrically conductive material electrically connected to the at least one of the one or more devices through the structure; forming a bump to electrically connect the at least one of the one or more devices to a device external to the electrical device, the bump comprising electrically conductive material; and forming a barrier material between the bump and the pad, the barrier material comprising electrically conductive material configured to resist electromigration, intermetallic compound reaction, or both electromigration and intermetallic compound reaction.

Example 35: The method of Example 34, wherein forming a structure comprises forming an interconnect that traverses an interlayer dielectric on the substrate.

Example 36: The method according to any one of Examples 34 and 35, wherein forming a barrier material comprises forming the barrier material with at least one of a metal, a conductive ceramic, or a conductive polymer.

Example 37: The method according to any one of Examples 34-36, wherein forming a barrier material comprises forming the barrier material with one or more carbon nanotubes.

Example 38: The method according to any one of Examples 34-37, further comprising forming a seed material, wherein forming a barrier material comprises forming the barrier material using the seed material.

Example 39: A semiconductor device, comprising: a pad comprising an electrically conductive material over a via; a barrier material on the pad, the barrier material comprising electrically conductive material selected to resist electromigration, intermetallic compound reaction, or both electromigration and intermetallic compound reaction; a bump comprising electrically conductive material on the barrier material.

Example 40: The semiconductor device of Example 39, further comprising a seed material between the pad and the barrier material.

Example 41: The semiconductor device of Example 39, wherein the barrier material comprises a chemical vapor deposition barrier material.

Example 42: The semiconductor device of Example 39, wherein the barrier material comprises a physical vapor deposition barrier material.

Example 43: The semiconductor device of Example 39, wherein the barrier material comprises a sputtered barrier material.

Example 44: A method of operating a computing device, the method comprising: operating a semiconductor device including: a top material defining a via formed therethrough; a pad comprising electrically conductive material lining the via, the pad electrically connected to at least one device of the semiconductor device; a barrier material on the pad, the barrier material comprising electrically conductive material selected to resist electromigration, intermetallic compound reaction, or both electromigration and intermetallic compound reaction; and a bump comprising electrically conductive material on the barrier material.

Example 45: The method of Example 44, further comprising further comprising conducting an electrical signal through the bump from a printed circuit board (PCB), wherein the semiconductor device is electrically connected to the PCB through the bump.

Example 46: The method according to any one of Examples 44-45, further comprising: operating a processor mounted on a substrate; operating a memory unit capable of storing data; operating a graphics processing unit; operating an antenna within the computing device; operating a display on the computing device; operating a battery within the computing device; operating a power amplifier within the processor; and operating a voltage regulator within the processor; wherein at least one of the processor, the memory unit, the graphics processing unit, the antenna, the display, the battery, the power amplifier, or the voltage regulator comprises the semiconductor device.

Example 47: A computer-readable storage medium having computer-readable instructions stored thereon, the computer-readable instructions configured to instruct one or more processors to perform at least a portion of the method according to any one of Examples 16-20, 24-38, and 44-46.

Example 48: A means for performing the method according to any one of Examples 16-20, 24-38, and 44-46.

### CONCLUSION

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A semiconductor device, comprising:
an interconnect;
a top material defining a via therethrough to the interconnect;
a pad comprising electrically conductive material on the interconnect and at least a portion of the top material;
a bump comprising electrically conductive material on the pad, the bump configured to electrically connect the interconnect to another device; and
a barrier material between the pad and the bump, the barrier material comprising a conductive material that is resistant to electromigration, intermetallic compound reaction, or both electromigration and intermetallic compound reaction.

2. The semiconductor device of claim 1, wherein the barrier material completely separates the bump from the pad.

3. The semiconductor device of claim 1, wherein the barrier material is conformal to a shape of the via.

4. The semiconductor device of claim 1, wherein the barrier material comprises a metal.

5. The semiconductor device of claim 1, wherein the barrier material comprises at least one metal selected from the group consisting of tantalum (Ta), tungsten (W), platinum (Pt), nickel (Ni), cobalt (Co), and silver (Ag).

6. The semiconductor device of claim 1, wherein the barrier material comprises a ceramic material.

7. The semiconductor device of claim 1, wherein the barrier material comprises a polymer material.

8. The semiconductor device of claim 1, wherein the bump comprises a planar bump.

9. The semiconductor device of claim 1, wherein the pad and the bump comprise the same electrically conductive material.

10. The semiconductor device of claim 1, wherein the bump comprises copper (Cu).

11. An electrochromic device, comprising:
one or more devices formed on or in a substrate;
a structure comprising a conductive material, the structure electrically connected to at least one of the one or more devices;
a top material on the structure, the top material defining a passage therethrough to the structure;
a pad on the structure, the pad comprising electrically conductive material electrically connected to the at least one of the one or more devices through the structure;
a bump to electrically connect the at least one of the one or more devices to a device external to the electronic device, the bump comprising electrically conductive material; and
a barrier material between the bump and the pad, the barrier material comprising electrically conductive material configured to resist electromigration, intermetallic compound reaction, or both electromigration and intermetallic compound reaction.

12. The electronic device of claim 11, wherein the structure comprises an interconnect that traverses an interlayer dielectric on the substrate.

13. The electronic device of claim 11, wherein the barrier material comprises at least one of a metal, a conductive ceramic, or a conductive polymer.

14. The electronic device of claim 11, wherein the barrier material comprises one or more carbon nanotubes.

15. The electronic device of claim 11, further comprising a seed material between the pad and the barrier material, the seed material comprising a material that was used to form the barrier material.

16. A method of manufacturing a semiconductor device, the method comprising:
forming a pad comprising an electrically conductive material over a via;
patterning photoresist around the via on the pad;
forming a barrier material on the pad, the barrier material comprising electrically conductive material selected to resist electromigration, intermetallic compound reaction, or both electromigration and intermetallic compound reaction; and
forming a bump comprising electrically conductive material on the barrier material.

17. The method of claim 16, wherein forming a barrier material on the pad comprises forming a seed material on the pad and forming the barrier material using the seed material.

18. The method of claim 16, wherein forming a barrier material on the pad comprises depositing the barrier material on the pad using chemical vapor deposition.

19. The method of claim 16, wherein forming a barrier material on the pad comprises depositing the barrier material on the pad using physical vapor deposition.

20. The method of claim 16, wherein forming a barrier material on the pad comprises sputtering the barrier material onto the pad.

21. A computing device, comprising:
a semiconductor device including:
a top material defining a via formed therethrough;
a pad comprising electrically conductive material lining the via, the pad electrically connected to at least one device of the semiconductor device;
a barrier material on the pad, the barrier material comprising electrically conductive material selected to resist electromigration, intermetallic compound reaction, or both electromigration and intermetallic compound reaction; and
a bump comprising electrically conductive material on the barrier material.

22. The computing device of claim 21, further comprising a printed circuit board (PCB), wherein the semiconductor device is electrically connected to the PCB through the bump.

23. The computing device of claim 21, further comprising:
a processor mounted on a substrate;
a memory unit capable of storing data;
a graphics processing unit;
an antenna within the computing device;
a display on the computing device;
a battery within the computing device;
a power amplifier within the processor; and
a voltage regulator within the processor;
wherein at least one of the processor, the memory unit, the graphics processing unit, the antenna, the display, the battery, the power amplifier, or the voltage regulator comprises the semiconductor device.
